(19) United States
(12) Patent Application Publication
(10) Pub. No.: US 2024/0243110 A1
(43) Pub. Date: Jul. 18, 2024

(54) SEMICONDUCTOR PACKAGE

(71) Applicant: Samsung Electronics Co., Ltd., Suwon-si (KR)

(72) Inventors: HYEONJEONG HWANG, Suwon-si (KR); SUNGEUN JO, Suwon-si (KR)

(21) Appl. No.: 18/235,643

(22) Filed: Aug. 18, 2023

(30) Foreign Application Priority Data
Jan. 13, 2023 (KR) 10-2023-0005550

(51) Int. Cl. H01L 25/10; H01L 23/00; H01L 23/367; H01L 23/498; H01L 23/538; H10B 80/00

(52) U.S. Cl. CPC H01L 25/105; H01L 23/3675; H01L 23/49816; H01L 23/49838; H01L 23/5386; H01L 24/16; H01L 24/32; H01L 24/73; H10B 80/00; H01L 2224/16146; H01L 2224/16225; H01L 2224/32137; H01L 2224/32145; H01L 2224/32225; H01L 2224/32245; H01L 2224/73204; H01L 2225/1005; H01L 2924/1438; H01L 2924/16235

(57) ABSTRACT

Disclosed is a semiconductor package comprising an interposer substrate, a chip stack on the interposer substrate and including first semiconductor chips that are vertically stacked, a second semiconductor chip on the interposer substrate and horizontally spaced apart from the chip stack, a molding layer on the interposer substrate and surrounding the chip stack and the second semiconductor chip, a redistribution layer on the molding layer, and a plurality of conductive posts that vertically penetrate the molding layer and connect the interposer substrate to the redistribution layer.

### CROSS-REFERENCE TO RELATED APPLICATION

This U.S. nonprovisional application claims priority under 35 U.S.C § 119 to Korean Patent Application No. 10-2023-0005550 filed on Jan. 13, 2023 in the Korean Intellectual Property Office, the disclosure of which is hereby incorporated by reference in its entirety.

### BACKGROUND

An aspect of the present inventive concepts relates to a semiconductor package, and more particularly, to a stacked semiconductor package.

With the development of electronic industry, electronic products increasingly demand high performance, high speed, and compact size. To meet such demands, there has recently been developed a packaging technology in which a plurality of semiconductor chips are mounted in a single package.

Portable devices have been increasingly demanded in recent electronic product markets, and as a result, it has been ceaselessly requested for reduction in size and weight of electronic parts mounted on the portable devices. In order to accomplish the reduction in size and weight of the electronic parts, there is need for technology to integrate a number of individual devices into a single package as well as technology to reduce individual sizes of mounting parts. In particular, it is desirable that a semiconductor package in which a plurality of devices are integrated has a compact size, improved thermal characteristics, and excellent electrical properties.

### SUMMARY

Some embodiments of the present inventive concepts provide a semiconductor package with increased integration and reduced size.

Some embodiments of the present inventive concepts provide a semiconductor package with improved thermal radiation properties.

According to some embodiments of the present inventive concepts, a semiconductor package may comprise: an interposer substrate; a chip stack on the interposer substrate and including first semiconductor chips that are vertically stacked; a second semiconductor chip on the interposer substrate and horizontally spaced apart from the chip stack; a molding layer disposed on the interposer substrate and surrounding a side surface of each of the chip stack and the second semiconductor chip; a redistribution layer on the molding layer; and a plurality of conductive posts that vertically penetrate the molding layer and connect the interposer substrate to the redistribution layer.

According to some embodiments of the present inventive concepts, a semiconductor package may comprise: a substrate; a chip stack on the substrate and including memory chips that are vertically stacked; a logic chip on the substrate and horizontally spaced apart from the chip stack; a molding layer that surrounds a side surface of each of the chip stack and the logic chip; a redistribution layer on the molding layer and having a through hole above the logic chip, the through hole vertically penetrating the redistribution layer; and a dummy chip in the through hole and contacting a top surface of the logic chip.

According to some embodiments of the present inventive concepts, a semiconductor package may comprise: a package substrate; an interposer substrate on the package substrate; a chip stack on the interposer substrate, the chip stack including first semiconductor chips that are vertically stacked; a second semiconductor chip on the interposer substrate and horizontally spaced apart from the chip stack; a molding layer disposed on the interposer substrate and surrounding a side surface of each of the chip stack and the second semiconductor chip; a redistribution layer on the molding layer; and a vertical connection terminal that vertically penetrates the molding layer and connects the interposer substrate to the redistribution layer.

### BRIEF DESCRIPTION OF DRAWINGS

FIG. 1 illustrates a plan view showing a semiconductor package according to some embodiments of the present inventive concepts.

FIGS. 2 to 11 illustrate cross-sectional views showing a semiconductor package according to some embodiments of the present inventive concepts.

FIG. 12 illustrates a plan view showing a semiconductor package according to some embodiments of the present inventive concepts.

FIG. 13 illustrates a cross-sectional view showing a semiconductor package according to some embodiments of the present inventive concepts.

FIG. 14 illustrates a plan view showing a semiconductor package according to some embodiments of the present inventive concepts.

FIG. 15 illustrates a cross-sectional view showing a semiconductor package according to some embodiments of the present inventive concepts.

FIG. 16 illustrates a plan view showing a semiconductor package according to some embodiments of the present inventive concepts.

FIG. 17 illustrates a cross-sectional view showing a semiconductor package according to some embodiments of the present inventive concepts.

FIG. 18 illustrates a plan view showing a semiconductor package according to some embodiments of the present inventive concepts.

FIG. 19 illustrates a cross-sectional view showing a semiconductor package according to some embodiments of the present inventive concepts.

FIG. 20 illustrates a plan view showing a semiconductor package according to some embodiments of the present inventive concepts.

FIG. 21 illustrates a cross-sectional view showing a semiconductor package according to some embodiments of the present inventive concepts.

FIG. 22 illustrates a plan view showing a semiconductor package according to some embodiments of the present inventive concepts.

FIG. 23 illustrates a cross-sectional view showing a semiconductor package according to some embodiments of the present inventive concepts.

FIGS. 24 to 28 illustrate cross-sectional views showing a method of fabricating a semiconductor package according to some embodiments of the present inventive concepts.

### DETAILED DESCRIPTION OF EMBODIMENTS

The following will now describe a semiconductor package according to the present inventive concepts with reference to the accompanying drawings.

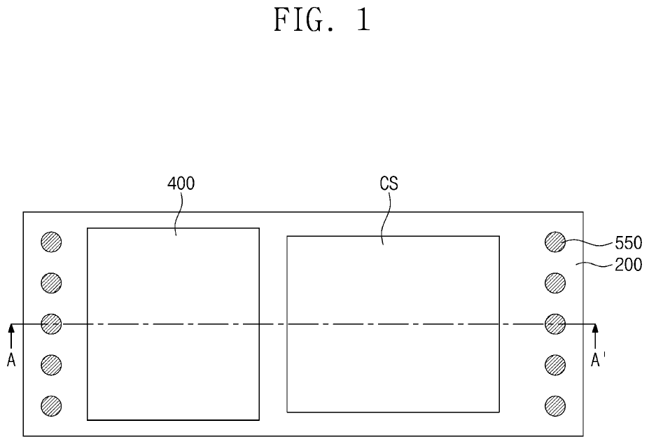

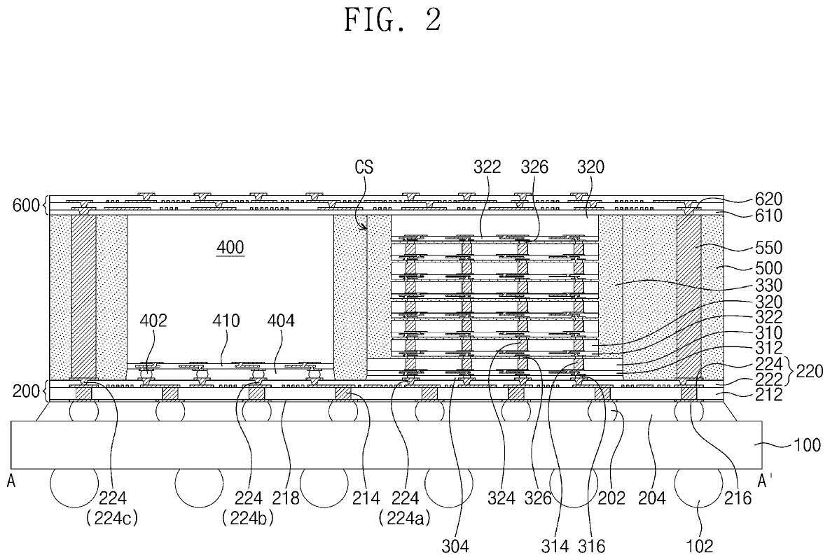

FIG. 1 illustrates a plan view showing a semiconductor package according to some embodiments of the present inventive concepts. FIGS. 2 to 4 illustrate cross-sectional views taken along line A-A′ of FIG. 1 which show a semiconductor package according to some embodiments of the present inventive concepts.

Referring to FIGS. 1 and 2, a package substrate 100 may be provided. The package substrate 100 may include a printed circuit board (PCB) having a signal pattern on a top surface thereof. Alternatively, the package substrate 100 may have a structure in which at least one dielectric layer and at least one wiring layer are alternately stacked. The package substrate 100 may have pads disposed on a top surface thereof.

A plurality of external terminals 102 may be disposed below the package substrate 100. For example, the external terminals 102 may be disposed on terminal pads provided on a bottom surface of the package substrate 100. The external terminals 102 may include or may be solder balls or solder bumps, and based on type and arrangement of the external terminals 102, a semiconductor package may be provided in the form of one of a ball grid array (BGA) type, a fine ball-grid array (FBGA) type, and a land grid array (LGA) type.

An interposer substrate 200 may be provided on the package substrate 100. The interposer substrate 200 may be a silicon interposer substrate. For example, the interposer substrate 200 may include a silicon layer 212, interposer vias 214 that vertically penetrate the silicon layer 212, interposer lower pads 216 provided on a bottom surface of the silicon layer 212 and coupled to the interposer vias 214, an interposer protection layer 218 that is provided on the bottom surface of the silicon layer 212 and surrounds the interposer lower pads 216, and a wiring member 220 provided on a top surface of the silicon layer 212.

The silicon layer 212 may be a silicon substrate. The interposer vias 214 may vertically completely penetrate the silicon layer 212. For example, top surfaces of the interposer vias 214 may be exposed on the top surface of the silicon layer 212, and bottom surfaces of the interposer vias 214 may be exposed on the bottom surface of the silicon layer 212. The interposer vias 214 may include or may be formed of metal, such as copper (Cu).

On the bottom surface of the silicon layer 212, the interposer lower pads 216 may be disposed on the bottom surfaces of the interposer vias 214. The interposer lower pads 216 may include or may be formed of metal, such as copper (Cu).

The interposer protection layer 218 may be disposed on the bottom surface of the silicon layer 212. The interposer protection layer 218 may expose bottom surfaces of the interposer lower pads 216. The interposer protection layer 218 may include or may be formed of a photo-imageable dielectric (PID). For example, the photo-imageable dielectric may include at least one selected from photosensitive polyimide, polybenzoxazole (PBO), phenolic polymers, and benzocyclobutene polymers.

The wiring member 220 may include one or more substrate wiring layers. Each of the substrate wiring layers may include a first substrate dielectric pattern 222 and a first substrate wiring pattern 224 in the first substrate dielectric pattern 222. The first substrate wiring pattern 224 may be electrically connected to the interposer vias 214. The first substrate dielectric pattern 222 may include or may be formed of a dielectric polymer or a photo-imageable dielectric (PID). The first substrate wiring pattern 224 may be provided in the first substrate dielectric pattern 222. The first substrate wiring pattern 224 may have a damascene structure. For example, the first substrate wiring pattern 224 may have a head portion and a tail portion that are connected with each other to form a single unitary piece. The head portion may be a wiring or pad portion that allows a wiring line in the wiring member 220 to extend horizontally. The tail portion may be a via portion that allows a wiring line in the wiring member 220 to be vertically connected to a certain component. The first substrate wiring pattern 224 may include or may be formed of a conductive material. For example, the first substrate wiring pattern 224 may include or may be formed of copper (Cu).

The head portion of the first substrate wiring pattern 224 included in an uppermost one of the substrate wiring layers may correspond to substrate pads 224a, 224b, and 224c (or interposer upper pads) of the interposer substrate 200. The substrate pads 224a, 224b, and 224c may include first substrate pads 224a for mounting a chip stack CS, second substrate pads 224b for mounting a second semiconductor chip 400, and third substrate pads 224c for connecting vertical connection terminals 550.

Differently from that shown in FIG. 2, the interposer substrate 200 may be a redistribution substrate. For example, the interposer substrate 200 may include at least two substrate wiring layers. Each of the substrate wiring layers may include a substrate dielectric pattern and a substrate wiring pattern in the substrate dielectric pattern. The substrate wiring pattern of one substrate wiring layer may be electrically connected to the substrate wiring pattern of adjacent another substrate wiring layer. The following description will focus on the embodiment of FIG. 2.

The interposer substrate 200 may be mounted on the top surface of the package substrate 100. The interposer substrate 200 may be provided thereon with substrate terminals 202 on a bottom surface thereof. The substrate terminals 202 may be provided between the pads of the package substrate 100 and the interposer lower pads 216 of the interposer substrate 200. The substrate terminals 202 may electrically connect the interposer substrate 200 to the package substrate 100. For example, the interposer substrate 200 may be flip-chip mounted on the package substrate 100. The substrate terminals 202 may include or may be solder balls or solder bumps. For example, the substrate terminals 202 may be disposed onto the interposer lower pads 216 of the interposer substrate 200, and then the interposer substrate 200 with the substrate terminals 202 is flipped over to be aligned with corresponding pads of the package substrate 100.

A first underfill layer 204 may be provided between the package substrate 100 and the interposer substrate 200. The first underfill layer 204 may surround the substrate terminals 202, while filling a space between the package substrate 100 and the interposer substrate 200.

The chip stack CS may be disposed on the interposer substrate 200. The chip stack CS may include a base substrate, first semiconductor chips 320 stacked on the base substrate, and a first molding layer 330 that surrounds the first semiconductor chips 320. The following will describe in detail a configuration of the chip stack CS.

The base substrate may be a base semiconductor chip 310. For example, the base substrate may be a wafer-level semiconductor substrate formed of a semiconductor, such as silicon (Si). In this description below, the base semiconductor chip 310 and the base substrate may indicate the same component and may be allocated with the same reference numeral.

The base semiconductor chip 310 may include a base circuit layer 312 and base through electrodes 314. The base circuit layer 312 may be provided on a bottom surface of the base semiconductor chip 310. The base circuit layer 312 may include an integrated circuit. For example, the base circuit layer 312 may be a memory circuit. For example, the base semiconductor chip 310 may be a memory chip, such as dynamic random access memory (DRAM), static random access memory (SRAM), magnetic random access memory (MRAM), or Flash memory. The base through electrode 314 may penetrate the base semiconductor chip 310 in a direction perpendicular to the top surface of the interposer substrate 200. The base through electrodes 314 may be electrically connected to the base circuit layer 312. The bottom surface of the base semiconductor chip 310 may be an active surface at which a plurality of transistors are formed. FIG. 2 depicts that the base substrate includes the base semiconductor chip 310, but the present inventive concepts are not limited thereto. According to some embodiments of the present inventive concepts, the base substrate may not include the base semiconductor chip 310.

The base semiconductor chip 310 may further include a protection layer and base connection terminals 316. The protection layer may be disposed on the bottom surface of the base semiconductor chip 310, thereby covering the base circuit layer 312. The protection layer may include or may be formed of silicon nitride (SiN). The base connection terminals 316 may be provided on the bottom surface of the base semiconductor chip 310. The base connection terminals 316 may be electrically connected to an integrated circuit, a power circuit, or an input/output circuit (e.g., the memory circuit) of the base circuit layer 312. The base connection terminals 316 may be exposed from the protection layer.

The first semiconductor chip 320 may be mounted on the base semiconductor chip 310. For example, the first semiconductor chip 320 and the base semiconductor chip 310 may constitute a chip-on-wafer (COW) structure. The first semiconductor chip 320 may have a width less than that of the base semiconductor chip 310.

The first semiconductor chip 320 may include a first circuit layer 322 and first through electrodes 324. The first circuit layer 322 may include a memory circuit. The first semiconductor chip 320 may be a memory chip, such as dynamic random access memory (DRAM), static random access memory (SRAM), magnetic random access memory (MRAM), or Flash memory. The first circuit layer 322 may include the same circuit as that of the base circuit layer 312, but the present inventive concepts are not limited thereto. The first through electrodes 324 may penetrate the first semiconductor chip 320 in a direction perpendicular to the top surface of the interposer substrate 200. The first through electrodes 324 may be electrically connected to the first circuit layer 322. The first semiconductor chip 320 may have a bottom surface or an active surface. The first semiconductor chip 320 may be provided with first chip bumps 326 on the bottom surface thereof. The first chip bumps 326 may be provided between the base semiconductor chip 310 and the first semiconductor chip 320 that are electrically connected to each other through the first chip bumps 326.

The first semiconductor chip 320 may be provided in plural. For example, a plurality of first semiconductor chips 320 may be stacked on the base semiconductor chip 310. The number of stacked first semiconductor chips 320 may be selected from a range of 4 to 32. The first chip bumps 326 may be provided between the first semiconductor chips 320. In this case, an uppermost first semiconductor chip 320 may not include the first through electrodes 324. In addition, the uppermost first semiconductor chip 320 may have a thickness greater than those of other first semiconductor chips 320 that underlie the uppermost first semiconductor chip 320.

Although not shown, an adhesion layer may be provided between the first semiconductor chips 320. The adhesion layer may include or may be a non-conductive film (NCF). The adhesion layer may be interposed between the first chip bumps 326 and between the first semiconductor chips 320, thereby preventing the occurrence of electrical short between the first chip bumps 326.

The first molding layer 330 may be disposed on a top surface of the base semiconductor chip 310. The first molding layer 330 may cover the base semiconductor chip 310 and surround the first semiconductor chips 320. The first molding layer 330 may have a top surface coplanar with that of the uppermost first semiconductor chip 320, and the uppermost first semiconductor chip 320 may be exposed from the first molding layer 330. The first molding layer 330 may include or may be formed of a dielectric polymer material. For example, the first molding layer 330 may include or may be formed of an epoxy molding compound (EMC).

Therefore, the chip stack S may be provided. The chip stack CS may be mounted on the interposer substrate 200. For example, the chip stack CS may be coupled through the base connection terminals 316 of the base semiconductor chip 310 to the first substrate pads 224a of the interposer substrate 200. The base connection terminals 316 may be provided between the base circuit layer 312 and the first substrate pads 224a of the interposer substrate 200.

A second underfill layer 304 may be provided between the interposer substrate 200 and the chip stack CS. The second underfill layer 304 may surround the base connection terminals 316, while filling a space between the interposer substrate 200 and the base semiconductor chip 310. The second underfill layer 304 may have a width which is the same as or greater than that of the chip stack CS.

The second semiconductor chip 400 may be disposed on the interposer substrate 200. The second semiconductor chip 400 may be disposed spaced apart from the chip stack CS. The second semiconductor chip 400 may have a thickness substantially the same as that of the chip stack CS. The second semiconductor chip 400 may include a semiconductor material, such as silicon (Si). The second semiconductor chip 400 may include a second circuit layer 410. The second circuit layer 410 may include a logic circuit. For example, the second semiconductor chip 400 may be a logic chip. The second semiconductor chip 400 may be a system-on-chip. A bottom surface of the second semiconductor chip 400 may be an active surface at which a plurality of transistors are formed, and a top surface of the second semiconductor chip 400 may be an inactive surface.

The second semiconductor chip 400 may be provided with second connection terminals 402 on the bottom surface thereof. The second connection terminals 402 may be electrically connected to an integrated circuit, a power circuit, or an input/output circuit (e.g., the logic circuit) of the second circuit layer 410.

The second semiconductor chip 400 may be mounted on the interposer substrate 200. For example, the second semiconductor chip 400 may be coupled through the second connection terminals 402 to the second substrate pads 224b of the interposer substrate 200. The second connection terminals 402 may be provided between the second substrate pads 224b of the interposer substrate 200 and the second circuit layer 410 of the second semiconductor chip 400.

A third underfill layer 404 may be provided between the interposer substrate 200 and the second semiconductor chip 400. The third underfill layer 404 may surround the second connection terminals 402, while filling a space between the interposer substrate 200 and the second semiconductor chip 400. The third underfill layer 404 may have a width which is the same as or greater than that of the second semiconductor chip 400.

A second molding layer 500 may be provided on the interposer substrate 200. The second molding layer 500 may cover the top surface of the interposer substrate 200. The second molding layer 500 may surround the chip stack CS and the second semiconductor chip 400. The second molding layer 500 may expose a top surface of the chip stack CS and the top surface of the second semiconductor chip 400. For example, the second molding layer 500 may have a top surface coplanar with that of the chip stack CS and that of the second semiconductor chip 400. The second molding layer 500 may include or may be formed of a dielectric material. For example, the second molding layer 500 may include or may be formed of an epoxy molding compound (EMC).

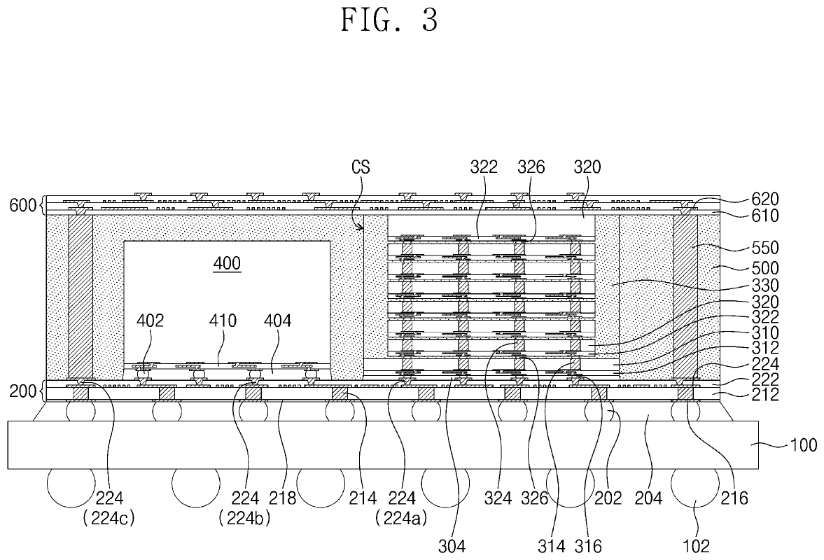

FIG. 2 depicts that the second molding layer 500, the chip stack CS, and the second semiconductor chip 400 have top surfaces located at the same level, but the present inventive concepts are not limited thereto. As shown in FIG. 3, the second semiconductor chip 400 may have a height less than that of the chip stack CS. For example, the top surface of the second semiconductor chip 400 may be located at a lower level than that of the top surface of the chip stack CS. The second molding layer 500 may cover the second semiconductor chip 400 and surround the chip stack CS. The top surface of the second molding layer 500 may be coplanar with that of the chip stack CS. The second semiconductor chip 400 may be buried in the second molding layer 500, and may not be exposed on the top surface of the second molding layer 500. Alternatively, the top surface of the chip stack CS may be located at a lower level than that of the top surface of the second semiconductor chip 400, and the top surface of the second semiconductor chip 400 may be coplanar with that of the second molding layer 500. In some embodiments, both of the top surface of the second semiconductor chip 400 and the top surface of the chip stack CS may be located at a lower level than that of the second molding layer 500, and both of the second semiconductor chip 400 and the chip stack CS may be buried in the second molding layer 500. The following description will focus on the embodiment of FIG. 2.

A redistribution layer 600 may be disposed on the second molding layer 500. The redistribution layer 600 may cover the chip stack CS and the second semiconductor chip 400. The redistribution layer 600 may be in contact with the top surface of the second molding layer 500. For example, the second molding layer 500 may fill a space between the interposer substrate 200 and the redistribution layer 600, and the chip stack CS and the second semiconductor chip 400 may be surrounded by the second molding layer 500 between the interposer substrate 200 and the redistribution layer 600. The redistribution layer 600 may be in contact with the top surface of the chip stack CS and the top surface of the second semiconductor chip 400. The term “contact,” as used herein, refers to a direct connection (i.e., physical touching) unless the context indicates otherwise.

The redistribution layer 600 may include one or more substrate wiring layers. The substrate wiring layers may be disposed on the second molding layer 500. The substrate wiring layers may be sequentially stacked on the second molding layer 500. Each of the substrate wiring layers may include a second substrate dielectric pattern 610 and a second substrate wiring pattern 620 in the second substrate dielectric pattern 610.

The second substrate dielectric pattern 610 may cover the second molding layer 500. Alternatively, the second substrate dielectric pattern 610 of one substrate wiring layer may cover another substrate wiring layer that is disposed thereunder. The second substrate dielectric pattern 610 may include or may be formed of a photo-imageable dielectric (PID). For example, the photo-imageable dielectric may include at least one selected from photosensitive polyimide, polybenzoxazole (PBO), phenolic polymers, and benzocyclobutene polymers. Alternatively, the second substrate dielectric pattern 610 may include or may be formed of a dielectric polymer.

The second substrate wiring pattern 620 may be provided in the second substrate dielectric pattern 610. The second substrate wiring pattern 620 may have a damascene structure. For example, the second substrate wiring pattern 620 may have a head portion and a tail portion that are connected with each other to form a single unitary piece. The head portion may be a wiring or pad portion that allows a wiring line in the redistribution layer 600 to extend horizontally. The tail portion may be a via portion that allows a wiring line in the redistribution layer 600 to be vertically connected to a certain component. The second substrate wiring pattern 620 may include or may be formed of a conductive material. For example, the second substrate wiring pattern 620 may include or may be formed of copper (Cu).

The substrate wiring layers may be stacked on the second molding layer 500 in a direction perpendicular to the top surface of the second molding layer 500. The substrate wiring layers may have configurations that are the same as or similar to each other. However, the second substrate wiring patterns 620 of the substrate wiring layers may have shapes or layouts that are different from each other if necessary.

The head portion of an uppermost one of the substrate wiring layers may correspond to upper pads of the redistribution layer 600.

The interposer substrate 200 and the redistribution layer 600 may be electrically connected with each other. For example, vertical connection terminals 550 may be provided between the interposer substrate 200 and the redistribution layer 600. The vertical connection terminals 550 may be through electrodes. The vertical connection terminals 550 may be disposed horizontally spaced apart from the chip stack CS and the second semiconductor chip 400. When viewed in a plan view, the chip stack CS and the second semiconductor chip 400 may be positioned in a region surrounded by the vertical connection terminals 550. For example, the chip stack CS and the second semiconductor chip 400 may be disposed between the vertical connection terminals 550. The vertical connection terminals 550 may be positioned on an outer section of the interposer substrate 200. The vertical connection terminals 550 may vertically penetrate from a bottom surface of the redistribution layer 600 through the second molding layer 500 and extend onto the top surface of the interposer substrate 200. The vertical connection terminals 550 may each have a width that is constant irrespective of distance from the top surface of the interposer substrate 200. Alternatively, the vertical connection terminals 550 may each have a width that decreases in a direction from the redistribution layer 600 toward the interposer substrate 200. The vertical connection terminals 550 may be coupled to the third substrate pads 224c of the interposer substrate 200. The vertical connection terminals 550 may be coupled to the second substrate wiring pattern 620 of a lowermost substrate wiring layer of the redistribution layer 600. For example, on the lowermost substrate wiring layer, the second substrate wiring pattern 620 may penetrate the second substrate dielectric pattern 610 positioned thereunder to be coupled to top surfaces of the vertical connection terminals 550. The vertical connection terminals 550 may be electrically connected through the interposer substrate 200 to the external terminals 102, the chip stack CS, or the second semiconductor chip 400. The vertical connection terminals 550 may include or may be a metal pillar. For example, the vertical connection terminals 550 may include or may be formed of copper (Cu) or tungsten (W).

According to some embodiments of the present inventive concepts, the redistribution layer 600 may be provided on the chip stack CS and the second semiconductor chip 400, and the vertical connection terminals 550 may connect the redistribution layer 600 and the interposer substrate 200 with each other. Therefore, a semiconductor chip, an electronic device, or an external apparatus may be separately mounted on the redistribution layer 600, and as a result, a semiconductor package may increase in a degree of integration. In addition, the interposer substrate 200 may be provided thereon with a circuit wiring line connected to the chip stack CS and the second semiconductor chip 400, and the circuit wiring line may also be provided above the chip stack CS and the second semiconductor chip 400. This configuration may allow the semiconductor chip, the electronic device, or the external apparatus connected to the chip stack CS and the second semiconductor chip 400 to be vertically stacked on the chip stack CS and the second semiconductor chip 400. Accordingly, it may be possible to provide a compact-sized semiconductor package that occupies a small planar area.

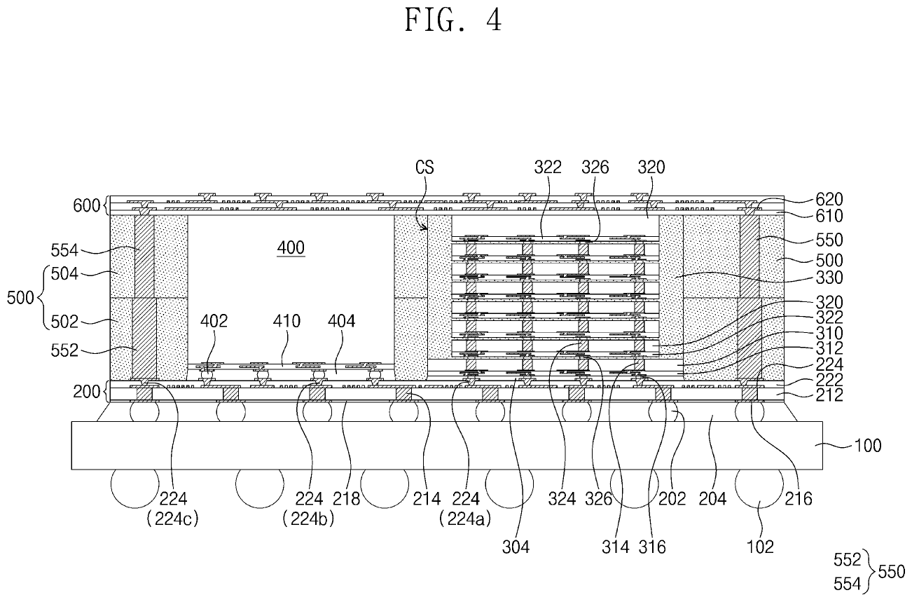

In FIG. 2, each of the vertical connection terminals 550 is illustrated as one conductive post that connects the interposer substrate 200 to the redistribution layer 600, but the present inventive concepts are not limited thereto. As shown in FIG. 4, the vertical connection terminals 550 may each include a lower post 552 that is connected the third substrate pad 224c of the interposer substrate 200 and an upper post 554 that is on the lower post 552 and connected to the redistribution layer 600. The lower post 552 may have a width greater than that of the upper post 554. In this case, the second molding layer 500 may include a first sub-molding layer 502 on the interposer substrate 200 and a second sub-molding layer 504 on the first sub-molding layer 502. An interface between the lower post 552 and the upper post 554 may be located at the same level as that of an interface between the first sub-molding layer 502 and the second sub-molding layer 504. In some embodiments, the first sub-molding layer 502 and the second sub-molding layer 504 may include or may be formed of the same material. The present invention is not limited thereto. For example, the first sub-molding layer 502 and the second sub-molding layer 504 may include or may be formed of different materials.

In the embodiments that follow, a detailed description of technical features repetitive to those discussed with reference to FIGS. 1 to 4 will be omitted for convenience of description, and a difference thereof will be discussed in detail. The same reference numerals may be allocated to the same components as those of the semiconductor package discussed above according to some embodiments of the present inventive concepts.

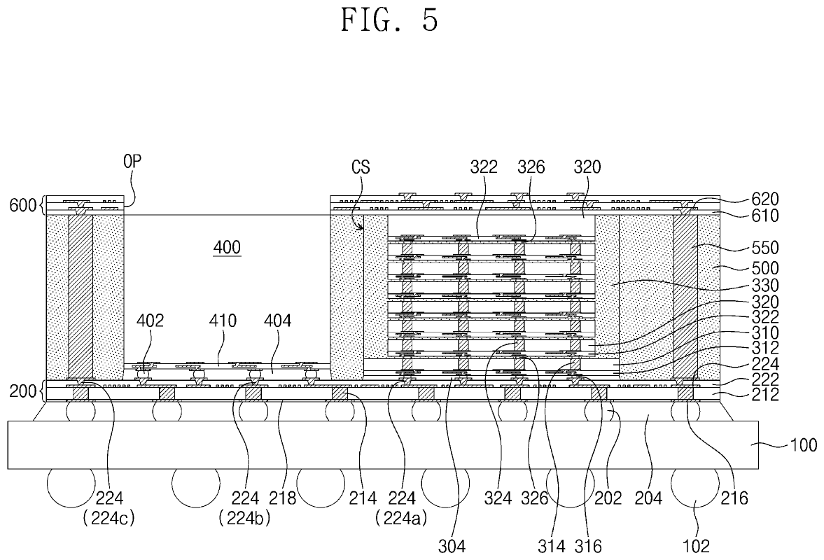

FIGS. 5 to 8 illustrate cross-sectional views showing a semiconductor package according to some embodiments of the present inventive concepts.

Referring to FIG. 5, the second semiconductor chip 400, the chip stack CS, and the second molding layer 500 may have top surfaces that are located at substantially the same level and are coplanar with each other.

The redistribution layer 600 may have an opening OP. The opening OP may be positioned above the second semiconductor chip 400. The opening OP may vertically completely penetrate the redistribution layer 600 to expose the top surface of the second semiconductor chip 400. The opening OP may have a width substantially the same as that of the second semiconductor chip 400. For example, the opening OP may have a planar shape substantially the same as that of the second semiconductor chip 400, and an entirety of the opening OP may overlap an entirety of the top surface of the second semiconductor chip 400. For example, the perimeter of the opening OP may vertically overlap of the perimeter of the top surface of the second semiconductor chip 400. The present inventive concepts, however, are not limited thereto, and the planar shape of the opening OP may be larger or smaller than that of the second semiconductor chip 400.

According to some embodiments of the present inventive concepts, the redistribution layer 600 may provide electrical wiring lines on the second semiconductor chip 400 and the chip stack CS, and the opening OP of the redistribution layer 600 may expose the top surface of the second semiconductor chip 400. Therefore, heat generated from the second semiconductor chip 400 may be discharged through the top surface of the second semiconductor chip 400. When the second semiconductor chip 400 includes a logic circuit, a large amount of heat may be generated from the second semiconductor chip 400 during operation thereof. The redistribution layer 600 does not cover the second semiconductor chip 400, and thus the heat may be effectively discharged via the opening OP of the redistribution layer 600. Accordingly, it may be possible to provide a semiconductor package with improved thermal radiation properties.

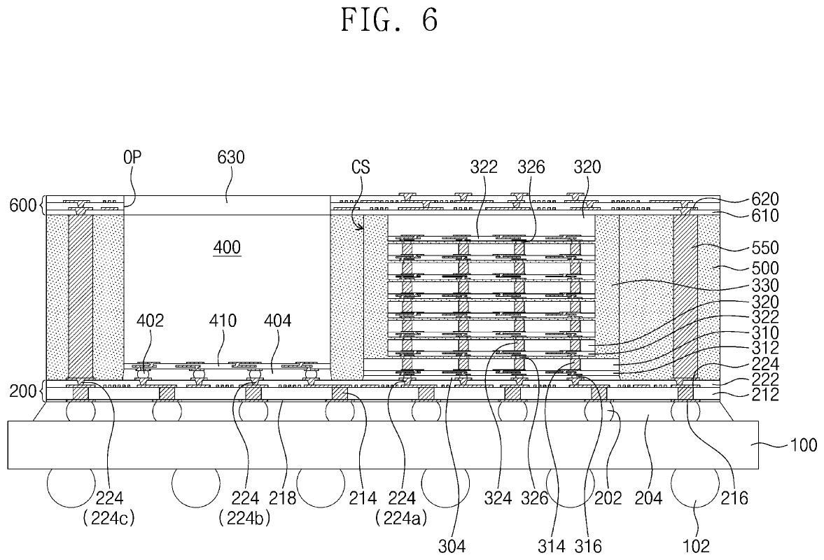

According to some embodiments, referring to FIG. 6, a semiconductor package may further include a first dummy chip 630 provided in the opening OP of the redistribution layer 600. The first dummy chip 630 may fill an internal space of the opening OP of the redistribution layer 600. The first dummy chip 630 may be in contact with the top surface of the second semiconductor chip 400. An interface between the first dummy chip 630 and the second semiconductor chip 400 may be located at the same level as that of the top surface of the second molding layer 500. The first dummy chip 630 may have a top surface located at the same level as that of a top surface of the redistribution layer 600. The present inventive concepts, however, are not limited thereto, and the top surface of the first dummy chip 630 may be located at a level higher or lower than that of the top surface of the redistribution layer 600. The first dummy chip 630 may have a thermal conductivity greater than that of the second substrate dielectric pattern 610 of the redistribution layer 600. The thermal conductivity of the first dummy chip 630 may be greater than that of the second semiconductor chip 400. The first dummy chip 630 may be a dummy chip formed of bulk silicon or metal. In some embodiments, the first dummy chip 630 may serve as a heat dissipator.

Although not shown, the first dummy chip 630 may be provided with a thermal interface material (TIM) layer. For example, the thermal interface material layer may be interposed between the second semiconductor chip 400 and the first dummy chip 630. The thermal interface material layer may be a heat transfer member that transmits heat from the second semiconductor chip 400 to the first dummy chip 630. The thermal interface material layer may include or may be formed of thermal grease, epoxy materials, or solid particles of metal such as indium. The thermal interface material layer may have adhesiveness and/or conductivity. The thermal interface material layer may be provided or not, if necessary.

According to some embodiments of the present inventive concepts, as the first dummy chip 630 is provided on the second semiconductor chip 400, heat generated from the second semiconductor chip 400 may be effectively discharged through the first dummy chip 630. Accordingly, it may be possible to provide a semiconductor package with improved thermal radiation properties.

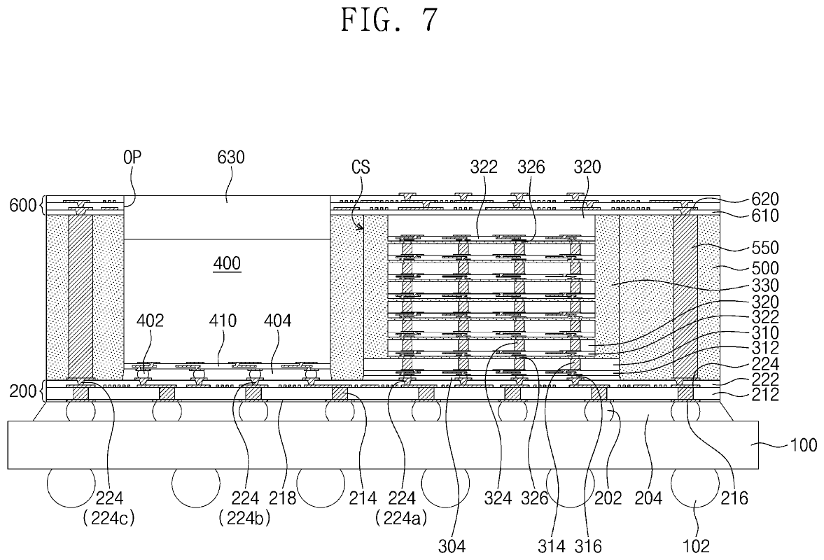

According to some embodiments, referring to FIG. 7, the second semiconductor chip 400 may have a height less than that of the chip stack CS. For example, the top surface of the second semiconductor chip 400 may be located at a lower level than that of the top surface of the chip stack CS.

The opening OP may vertically penetrate the redistribution layer 600. In addition, on the second semiconductor chip 400, the opening OP may vertically penetrate the second molding layer 500. For example, the opening OP may penetrate the redistribution layer 600 and the second molding layer 500 to expose the top surface of the second semiconductor chip 400.

The first dummy chip 630 may be provided in the opening OP. The first dummy chip 630 may fill an internal space of the opening OP of the redistribution layer 600. The first dummy chip 630 may be in contact with the top surface of the second semiconductor chip 400. An interface between the first dummy chip 630 and the second semiconductor chip 400 may be located at a lower level than that of the top surface of the second molding layer 500. The first dummy chip 630 may have a top surface located at the same level as that of a top surface of the redistribution layer 600. The present inventive concepts, however, are not limited thereto, and the top surface of the first dummy chip 630 may be located at a level higher or lower than that of the top surface of the redistribution layer 600. The first dummy chip 630 may have a thermal conductivity greater than that of the second substrate dielectric pattern 610 of the redistribution layer 600. The first dummy chip 630 may be a dummy chip formed of bulk silicon or metal. In some embodiments, the first dummy chip 630 may serve as a heat dissipator.

According to some embodiments of the present inventive concepts, as the second semiconductor chip 400 is provided thereon with the first dummy chip 630 that penetrates the redistribution layer 600 and the second molding layer 500 to thereby contact the second semiconductor chip 400, the first dummy chip 630 may assure higher radiation efficiency of heat generated from the second semiconductor chip 400 that is buried in the second molding layer 500 due to a small height thereof. For example, when the top surface of the second semiconductor chip 400 is lower than the top surface of the redistribution layer 600 without the first dummy chip 630 disposed on the second semiconductor chip 400, the heat generated from the second semiconductor chip 400 may be confined in the opening OP and the heat dissipation of the second semiconductor chip 400 may be limited compared to when the top surface of the second semiconductor chip 400 is higher than or at the same level with the top surface of the redistribution layer 600 or compared to when the first dummy chip 630 is disposed on the top surface of the second semiconductor chip 400. Accordingly, it may be possible to provide a semiconductor package with improved thermal radiation properties.

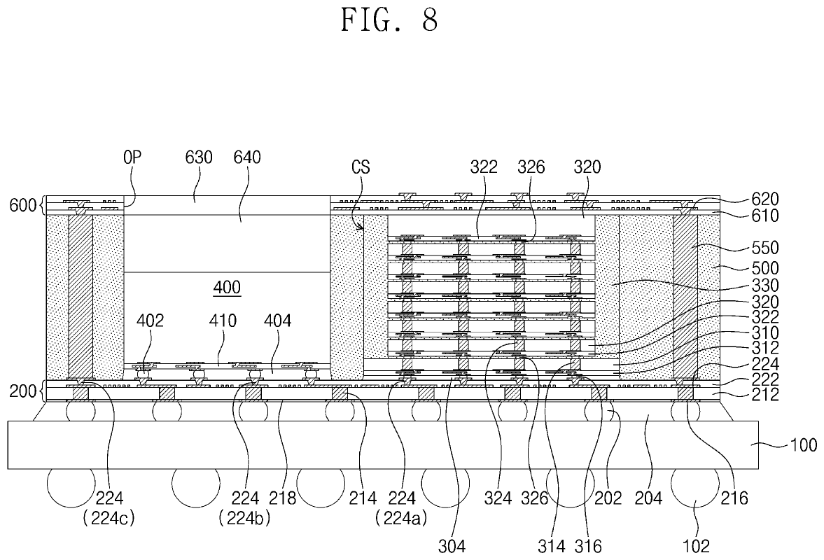

According to some embodiments, referring to FIG. 8, a thermal radiation member 640 may be further provided between the second semiconductor chip 400 and the first dummy chip 630.

The second semiconductor chip 400 may have a height less than that of the chip stack CS. For example, the top surface of the second semiconductor chip 400 may be located at a lower level than that of the top surface of the chip stack CS.

The opening OP may vertically penetrate the redistribution layer 600. In addition, on the second semiconductor chip 400, the opening OP may vertically penetrate the second molding layer 500. For example, the opening OP may penetrate the redistribution layer 600 and the second molding layer 500 to expose the top surface of the second semiconductor chip 400.

The thermal radiation member 640 may be provided in the opening OP. The thermal radiation member 640 may fill a lower portion of the opening OP. The thermal radiation member 640 may be in contact with the top surface of the second semiconductor chip 400. An interface between the thermal radiation member 640 and the second semiconductor chip 400 may be located at a lower level than that of the top surface of the second molding layer 500. The thermal radiation member 640 and the redistribution layer 600 may have top surfaces that are located at the same level and are coplanar with each other. The thermal radiation member 640 may have a thermal conductivity greater than that of the second substrate dielectric pattern 610. The thermal conductivity of the thermal radiation member 640 may be greater than that of the second semiconductor chip 400. The thermal radiation member 640 may include or may be formed of bulk silicon or metal.

The first dummy chip 630 may be provided in the opening OP. The first dummy chip 630 may fill an upper portion of the opening OP. The first dummy chip 630 may be in contact with the top surface of the thermal radiation member 640. An interface between the first dummy chip 630 and the thermal radiation member 640 may be located at the same level as that of the top surface of the second molding layer 500. The first dummy chip 630 may have a top surface located at the same level as that of a top surface of the redistribution layer 600. The present inventive concepts, however, are not limited thereto, and the top surface of the first dummy chip 630 may be located at a level higher or lower than that of the top surface of the redistribution layer 600.

According to some embodiments of the present inventive concepts, as the thermal radiation member 640 and the first dummy chip 630 are provided on the second semiconductor chip 400, the first dummy chip 630 may assure higher radiation efficiency of heat generated from the second semiconductor chip 400 that is buried in the second molding layer 500 due to a small height thereof. For example, when the top surface of the second semiconductor chip 400 is lower than the top surface of the redistribution layer 600 without the first dummy chip 630 and the thermal radiation member 640 disposed on the second semiconductor chip 400, the heat generated from the second semiconductor chip 400 may be confined in the opening OP and the heat dissipation of the second semiconductor chip 400 may be limited compared to when the top surface of the second semiconductor chip 400 is higher than or at the same level with the top surface of the redistribution layer 600 or compared to when the first dummy chip 630 and the thermal radiation member 640 are disposed on the top surface of the second semiconductor chip 400. Accordingly, it may be possible to provide a semiconductor package with improved thermal radiation properties.

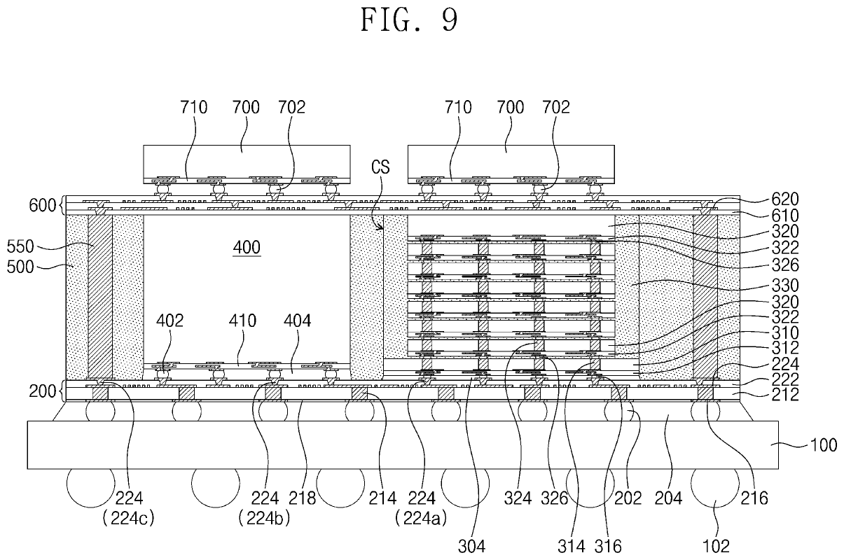

FIGS. 9 to 11 illustrate cross-sectional views showing a semiconductor package according to some embodiments of the present inventive concepts.

Referring to FIG. 9, third semiconductor chips 700 may be provided on the redistribution layer 600.

The third semiconductor chips 700 may include a semiconductor material, such as silicon (Si). The third semiconductor chips 700 may each include a third circuit layer 710. The third circuit layer 710 may include a logic circuit. The third semiconductor chips 700 may be logic chips. Alternatively, the third semiconductor chips 700 may include a memory device, a passive device, a connector device, or any kinds of an electronic device. A bottom surface of the third semiconductor chip 700 may be an active surface at which a plurality of transistors are formed, and a top surface of the third semiconductor chip 700 may be an inactive surface.

The third semiconductor chip 700 may be provided with third connection terminals 702 on the bottom surface thereof. The third connection terminals 702 may be electrically connected to an integrated circuit, a power circuit, or an input/output circuit (or the logic circuit) of the third circuit layer 710.

The third semiconductor chips 700 may be mounted on the redistribution layer 600. For example, the third semiconductor chips 700 may be coupled through the third connection terminals 702 to the second substrate wiring pattern 620 of the redistribution layer 600. The third connection terminals 702 may be provided between the second substrate wiring pattern 620 of the redistribution layer 600 and the third circuit layer 710 of the third semiconductor chip 700.

Although not shown, an underfill layer may be provided between the redistribution layer 600 and the third semiconductor chips 700. The underfill layer may surround the third connection terminals 702, while filling spaces between the redistribution layer 600 and the third semiconductor chips 700.

FIG. 9 depicts that the third semiconductor chips 700 are flip-chip mounted on the redistribution layer 600, but the present inventive concepts are not limited thereto. The third semiconductor chips 700 may be wire-bonding mounted on the redistribution layer 600.

According to some embodiments of the present inventive concepts, the third semiconductor chips 700 may be additionally provided on the second semiconductor chip 400 and the chip stack CS. Therefore, it may be possible to provide a semiconductor package with increased integration. In addition, on the interposer substrate 200, the third semiconductor chips 700 may be disposed above the chip stack CS and the second semiconductor chip 400. Accordingly, it may be possible to provide a compact-sized semiconductor package that occupies a small planar area.

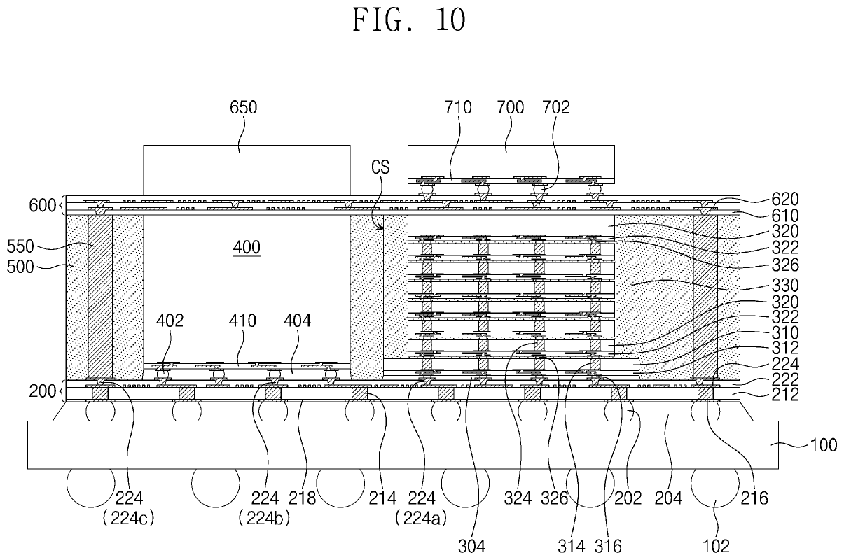

According to some embodiments, referring to FIG. 10, a semiconductor package may further include a second dummy chip 650 provided on the redistribution layer 600. The second dummy chip 650 may be attached to or mounted on the top surface of the redistribution layer 600. For example, the second dummy chip 650 may be attached to the top surface of the redistribution layer 600 through an adhesion layer provided on a bottom surface of the second dummy chip 650. The bottom surface of the second dummy chip 650 may contact the top surface of the redistribution layer 600 or may be attached to the top surface of the redistribution layer 600 using an adhesion layer. The second dummy chip 650 may be positioned above the second semiconductor chip 400. The second dummy chip 650 may be spaced apart from the third semiconductor chip 700. The second dummy chip 650 may have a thermal conductivity greater than that of the second substrate dielectric pattern 610 of the redistribution layer 600. The second dummy chip 650 may be a dummy chip formed of bulk silicon or metal.

According to some embodiments of the present inventive concepts, as the second dummy chip 650 is provided above the second semiconductor chip 400, heat may be effectively discharged from the second semiconductor chip 400. Thus, it may be possible to provide a semiconductor package with increased thermal radiation properties.

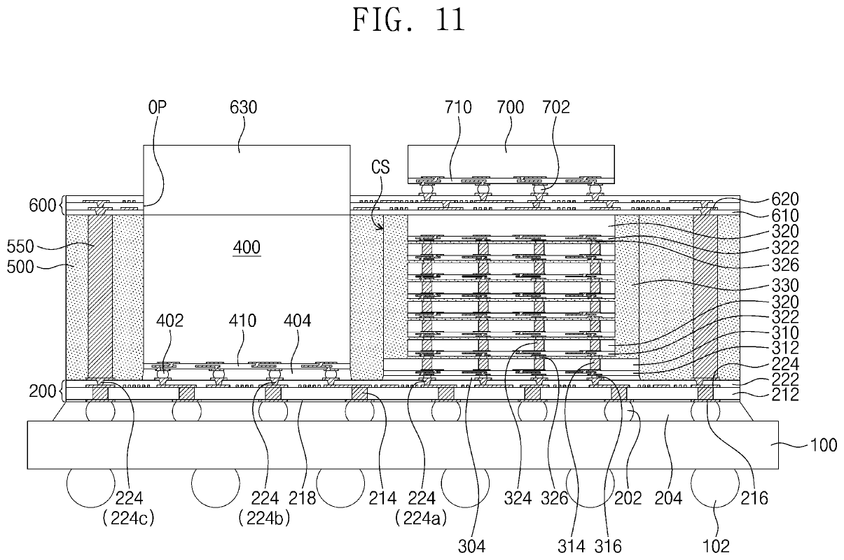

According to some embodiments, referring to FIG. 11, the redistribution layer 600 may have an opening OP. The opening OP may be positioned above the second semiconductor chip 400. The opening OP may vertically completely penetrate the redistribution layer 600 to expose the top surface of the second semiconductor chip 400.

The first dummy chip 630 may be provided in the opening OP of the redistribution layer 600. The first dummy chip 630 may fill an internal space of the opening OP of the redistribution layer 600. The first dummy chip 630 may be in contact with the top surface of the second semiconductor chip 400. The top surface of the first dummy chip 630 may be higher than the top surface of the redistribution layer 600. In some embodiments, the top surface of the first dummy chip 630 may be coplanar with a top surface of the third semiconductor chip 700.

According to some embodiments of the present inventive concepts, as the third semiconductor chip 700 is provided on the redistribution layer 600, a semiconductor package may increase in integration, and as the first dummy chip 630 is provided to contact the top surface of the second semiconductor chip 400, the semiconductor package may improve in thermal radiation efficiency.

FIGS. 1 to 11 depict that the vertical connection terminals 550 are positioned on an outer section of the interposer substrate 200, but the present inventive concepts are not limited thereto.

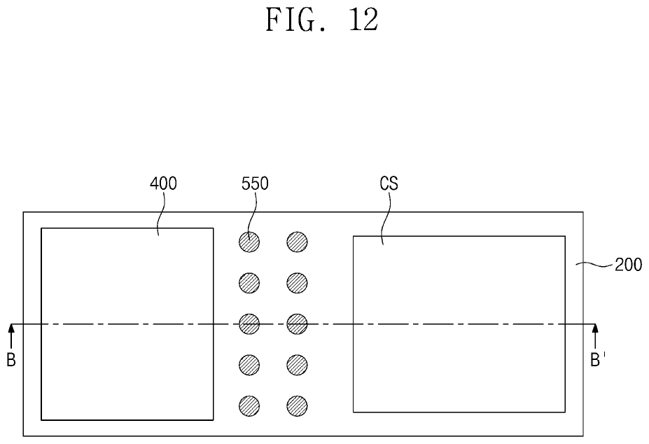

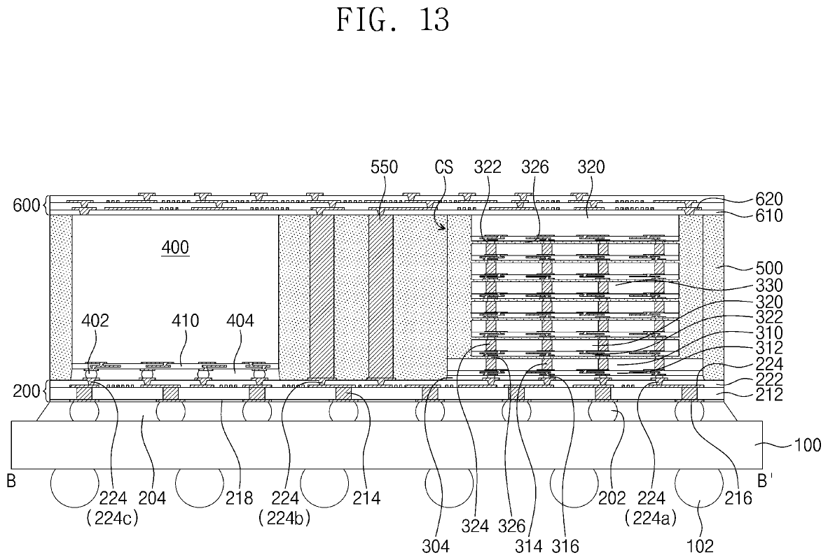

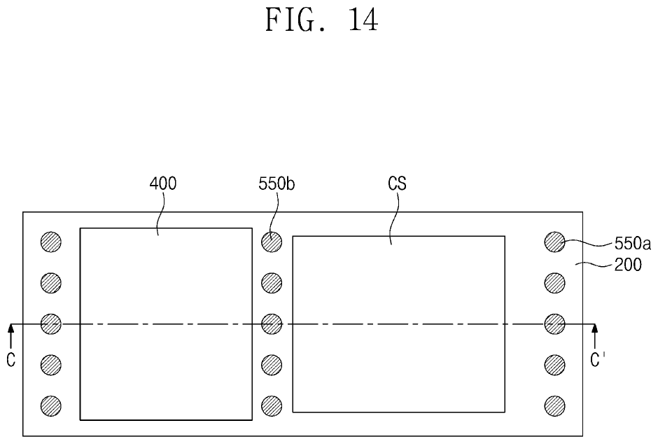

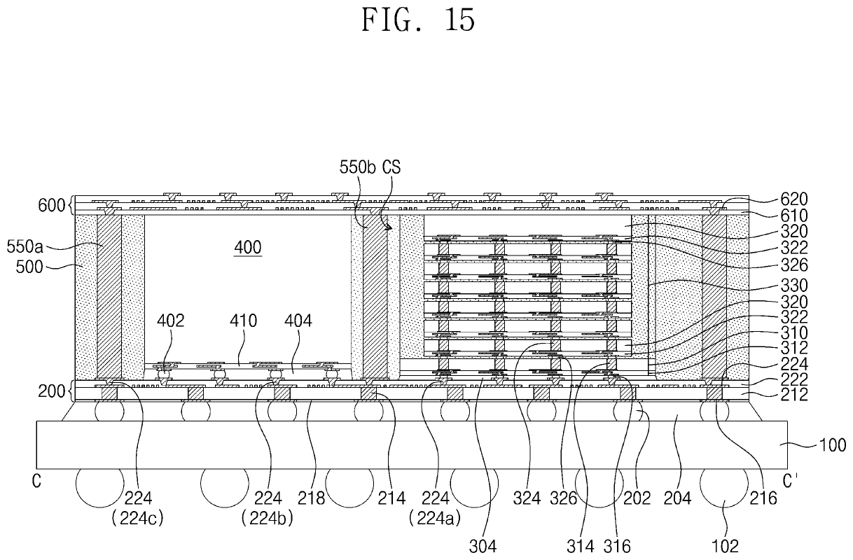

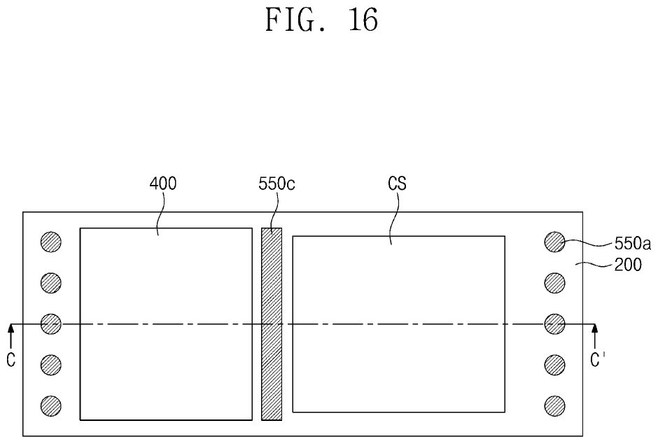

FIG. 12 illustrates a plan view showing a semiconductor package according to some embodiments of the present inventive concepts. FIG. 13 illustrates a cross-sectional view taken along line B-B′ of FIG. 12 which shows a semiconductor package according to some embodiments of the present inventive concepts. FIG. 14 illustrates a plan view showing a semiconductor package according to some embodiments of the present inventive concepts. FIG. 15 illustrates a cross-sectional view taken along line C-C′ of FIG. 14 which shows a semiconductor package according to some embodiments of the present inventive concepts. FIG. 16 illustrates a plan view showing a semiconductor package according to some embodiments of the present inventive concepts.

Referring to FIGS. 12 and 13, when viewed in a plan view, the vertical connection terminals 550 may be disposed between the chip stack CS and the second semiconductor chip 400. The vertical connection terminals 550 may be arranged along a direction that runs across between the chip stack CS and the second semiconductor chip 400. For example, when viewed in a plan view, the vertical connection terminals 550 may be arranged along facing side surfaces of the chip stack CS and the second semiconductor chip 400.

Alternatively, referring to FIGS. 14 and 15, first vertical connection terminals 550a of the vertical connection terminals 550 may be positioned on an edge of the interposer substrate 200. For example, the chip stack CS and the second semiconductor chip 400 may be disposed between the first vertical connection terminals 550a. Second vertical connection terminals 550b of the vertical connection terminals 550 may be disposed between the chip stack CS and the second semiconductor chip 400. The second vertical connection terminals 550b may be arranged along a direction that runs across between the chip stack CS and the second semiconductor chip 400. For example, when viewed in a plan view, the second vertical connection terminals 550b may be arranged along facing side surfaces of the chip stack CS and the second semiconductor chip 400.

According to some embodiments of the present inventive concepts, conductive vertical connection terminals (e.g., the conductive vertical connection terminals 550 of FIG. 12 and the second conductive vertical connection terminals 550b of FIG. 14) may be disposed between the chip stack CS and the second semiconductor chip 400. Between the chip stack CS and the second semiconductor chip 400, the vertical connection terminals may shield electromagnetic waves generated from the chip stack CS or the second semiconductor chip 400 to reduce electromagnetic interference between the chip stack CS and the second semiconductor chip 400. As a result, it may be possible to provide a semiconductor package with increased electrical properties.

According to some embodiments, as shown in FIG. 16, a third vertical connection terminal 550c of the vertical connection terminals 550 may have a partition shape and may be provided between the chip stack CS and the second semiconductor chip 400. For example, when viewed in a plan view, the third vertical connection terminal 550c may have a partition shape that extends in a direction that runs across between the chip stack CS and the second semiconductor chip 400.

According to some embodiments of the present inventive concepts, the third vertical connection terminal 550c may completely run across between the chip stack CS and the second semiconductor chip 400, and may effectively shield electromagnetic waves generated from the chip stack CS or the second semiconductor chip 400. For example, when viewed in a plan view, the third vertical connection terminal 550c may be a single terminal disposed between the chip stack CS and the second semiconductor chip 400, and may have a bar shape extending lengthwise along facing side surfaces of the chip stack CS and the second semiconductor chip 400. In some embodiments, the third vertical connection terminal 550c may have a length equal to or greater than the shorter length of the facing side surfaces of the chip stack CS and the second semiconductor chip 400. As a result, it may be possible to provide a semiconductor package with increased electrical properties.

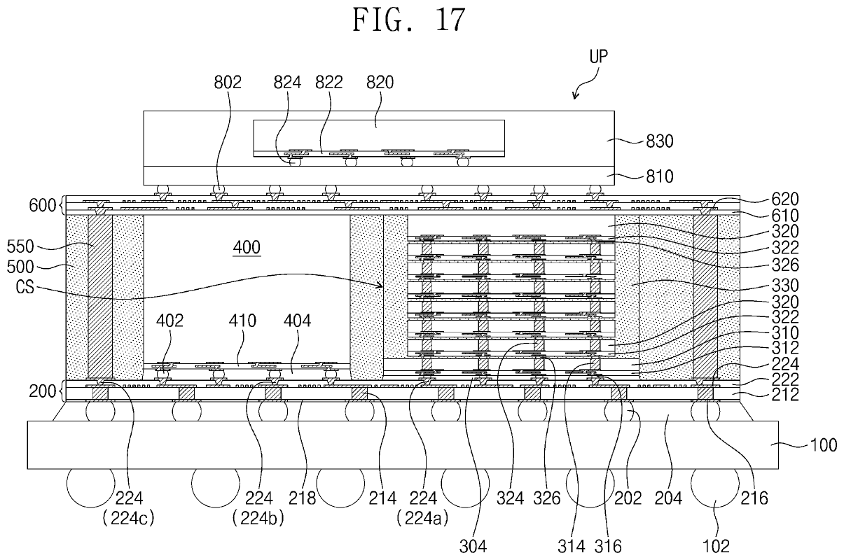

FIG. 17 illustrates a cross-sectional view showing a semiconductor package according to some embodiments of the present inventive concepts.

Referring to FIG. 17, the semiconductor package discussed with reference to FIGS. 1 to 8 may be a lower package.

An upper package UP may be provided on the redistribution layer 600. The upper package UP may include an upper package substrate 810, an upper semiconductor chip 820, and an upper molding layer 830. The upper package substrate 810 may be a printed circuit board (PCB). Alternatively, the upper package substrate 810 may be a redistribution layer. The upper package substrate 810 may be provided with metal pads on a bottom surface thereof.

An upper semiconductor chip 820 may be disposed on the upper package substrate 810. The upper semiconductor chip 820 may include integrated circuits, and the integrated circuits may include a memory circuit, a logic circuit, or a combination thereof. The upper semiconductor chip 820 may be different type of a semiconductor chip from the first semiconductor chips 320 and the second semiconductor chip 400. The upper semiconductor chip 820 may include a fourth circuit layer 822. The fourth circuit layer 822 may include a logic circuit.

The upper semiconductor chip 820 may be provided with fourth connection terminals 824 provided on the bottom surface thereof. The fourth connection terminals 824 may be electrically connected to an integrated circuit, a power circuit, or an input/output circuit (or the logic circuit) of the fourth circuit layer 822.

The upper semiconductor chip 820 may be mounted on the upper package substrate 810. For example, the upper semiconductor chip 820 may be coupled through the fourth connection terminals 824 to upper substrate pads of the upper package substrate 810. The fourth connection terminals 824 may be provided between the upper substrate pads of the upper package substrate 810 and chip pads of the upper semiconductor chip 820.

The upper package substrate 810 may be provided thereon with the upper molding layer 830 that covers the upper semiconductor chip 820. The upper molding layer 830 may include or may be formed of a dielectric polymer, such as an epoxy-based polymer.

Conductive terminals 802 may be disposed between the redistribution layer 600 and the upper package UP. The conductive terminals 802 may be interposed between the second substrate wiring pattern 620 of the redistribution layer 600 and lower substrate pads of the upper package substrate 810, thereby electrically connecting the second substrate wiring pattern 620 to the lower substrate pads. Therefore, the upper package UP may be electrically connected to the second semiconductor chip 400 and the chip stack CS through the redistribution layer 600, the vertical connection terminals 550, and the interposer substrate 200.

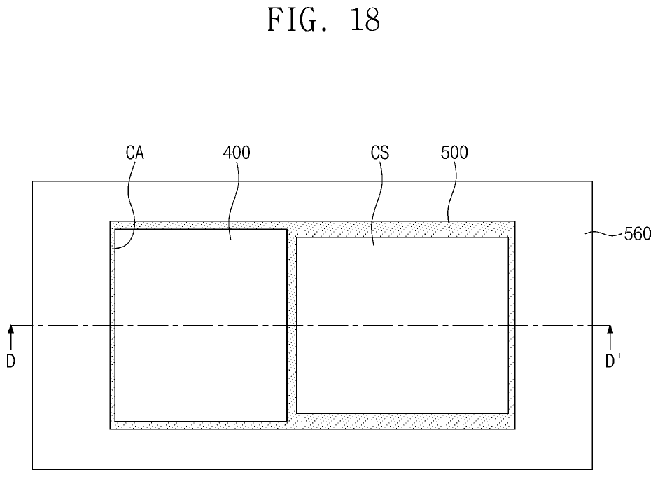

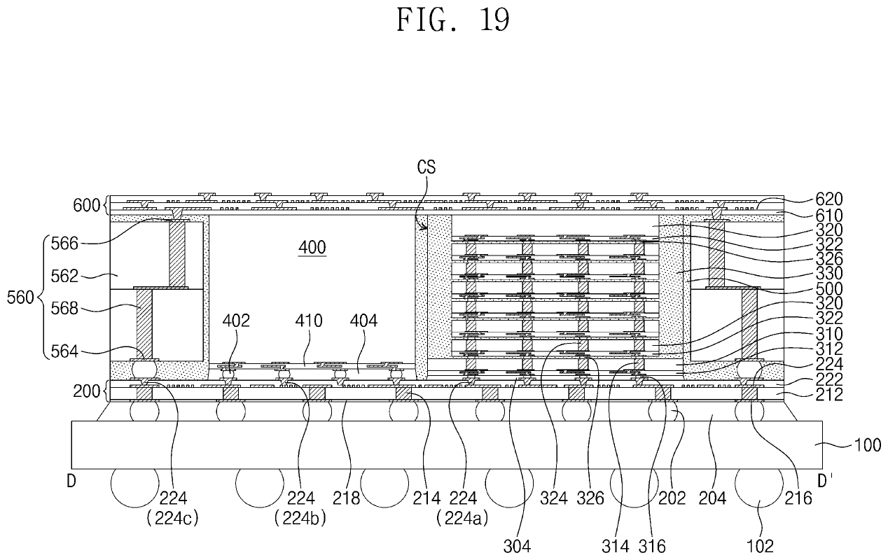

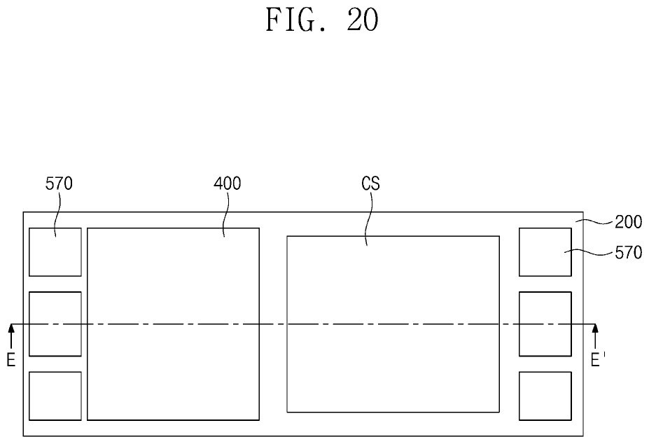

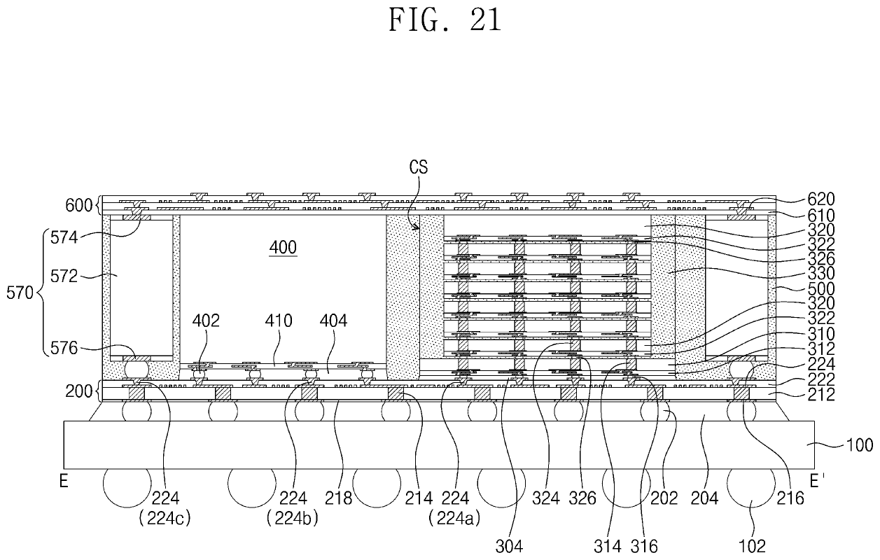

FIG. 18 illustrates a plan view showing a semiconductor package according to some embodiments of the present inventive concepts. FIG. 19 illustrates a cross-sectional view taken along line D-D′ of FIG. 18 which shows a semiconductor package according to some embodiments of the present inventive concepts. FIG. 20 illustrates a plan view showing a semiconductor package according to some embodiments of the present inventive concepts. FIG. 21 illustrates a cross-sectional view taken along line E-E′ of FIG. 20 which shows a semiconductor package according to some embodiments of the present inventive concepts.

In FIGS. 1 to 17, the vertical connection terminals 550 are illustrated as conductive posts, but the present inventive concepts are not limited thereto.

Referring to FIGS. 18 and 19, a connection substrate 560 may be provided as vertical connection terminals.

The connection substrate 560 may include an opening CA that penetrates therethrough. For example, the opening CA may be shaped like an open hole that extends from a top surface of the connection substrate 560 to a bottom surface thereof. A bottom surface of the opening CA may be spaced apart from the top surface of the interposer substrate 200.

The connection substrate 560 may include a base layer 562 and a conductive member as a connection pattern provided in the base layer 562. The conductive member may correspond to the vertical connection terminals 550 of FIG. 1. For example, the conductive member may have a wiring structure that vertically connects the interposer substrate 200 to the redistribution layer 600. Compared to the opening CA, the conductive member may be disposed on an outer section of the connection substrate 560. The conductive member may include lower pads 564, upper pads 566, and vias 568. The lower pads 564 may be disposed on the bottom surface of the connection substrate 560. The upper pads 566 may be disposed on the top surface of the connection substrate 560. The vias 568 may penetrate the base layer 562 and may electrically connect the lower pads 564 to the upper pads 566. The base layer 562 may include or may be formed of silicon oxide (SiO). The upper pads 566, the lower pads 564, and the vias 568 may include or may be formed of a conductor or metal, such as copper (Cu).

The connection substrate 560 may be mounted on the interposer substrate 200. For example, the connection substrate 560 may be coupled to the third substrate pads 224c of the interposer substrate 200 through connection substrate pads provided on the lower pads 564. Therefore, the connection substrate 560 may be electrically connected to the second semiconductor chip 400 and the chip stack CS.

The second semiconductor chip 400 and the chip stack CS may be disposed on the interposer substrate 200. The second semiconductor chip 400 and the chip stack CS may be disposed in the opening CA of the connection substrate 560.

The second molding layer 500 may be provided on the interposer substrate 200. The second molding layer 500 may cover the second semiconductor chip 400 and the chip stack CS in the opening CA of the connection substrate 560. For example, the second molding layer 500 may surround a side surface of each of the second semiconductor chip 400 and the chip stack CS. In this configuration, the second molding layer 500 may fill a gap between the connection substrate 560 and the second semiconductor chip 400 and a gap between the connection substrate 560 and the chip stack CS. In addition, the second molding layer 500 may fill a space between the connection substrate 560 and the interposer substrate 200. The second molding layer 500 may cover the top surface of the connection substrate 560. Alternatively, the second molding layer 500 may not cover the top surface of the connection substrate 560.

The redistribution layer 600 may be disposed on a top surface of the second molding layer 500, the top surface of the second semiconductor chip 400, and the top surface of the chip stack CS. The redistribution layer 600 may be coupled to the connection substrate 560. For example, the second substrate wiring pattern 620 of the redistribution layer 600 may be coupled to the upper pads 566 of the connection substrate 560.

According to some embodiments, referring to FIGS. 20 and 21, wiring chips 570 may be provided as vertical connection terminals. The wiring chips 570 may be spaced apart from each other on an outer section of the interposer substrate 200. FIG. 20 depicts that the wiring chips 570 have the same shape, but the wiring chips 570 may have shapes that are changed based on the number and pattern of required wiring lines.

The wiring chips 570 may be chips for vertical connection. Each of the wiring chips 570 may include a wiring member 572, upper pads 574 provided on a top surface of the wiring member 572, and lower pads 576 provided on a bottom surface of the wiring member 572. The wiring member 572 may have a wiring pattern therein. For example, the wiring member 572 may include a semiconductor substrate and the wiring pattern formed in the semiconductor substrate. The wiring member 572 may electrically connect the upper pads 574 to the lower pads 576.

The wiring chips 570 may be mounted on the interposer substrate 200. For example, the wiring chips 570 may be flip-chip mounted on the interposer substrate 200. The wiring chips 570 may be coupled to the third substrate pads 224c of the interposer substrate 200 through wiring chip terminals provided on the lower pads 576. Therefore, the lower pads 576 may be electrically connected to the second semiconductor chip 400 and the chip stack CS.

The second molding layer 500 may be provided on the interposer substrate 200. The second molding layer 500 may surround the second semiconductor chip 400, the chip stack CS, and the wiring chips 570. In this configuration, the second molding layer 500 may fill a gap between the wiring chip 570 and the second semiconductor chip 400 and a gap between the wiring chip 570 and the chip stack CS. In addition, the second molding layer 500 may fill a space between the wiring chip 570 and the interposer substrate 200. The second molding layer 500 may cover top surfaces of the wiring chips 570. Alternatively, the second molding layer 500 may not cover the top surfaces of the wiring chips 570.

The redistribution layer 600 may be disposed on the top surfaces of the wiring chips 570, the top surface of the second semiconductor chip 400, and the top surface of the chip stack CS. The redistribution layer 600 may be coupled to the wiring chips 570. For example, the second substrate wiring pattern 620 of the redistribution layer 600 may be coupled to the upper pads 574 of the wiring chips 570.

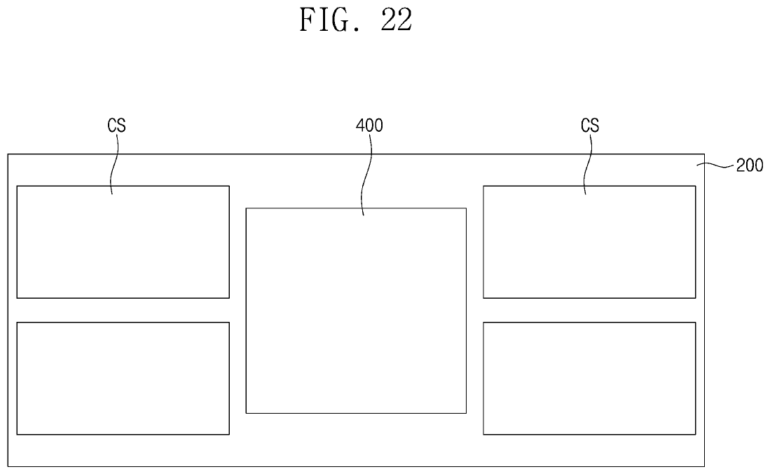

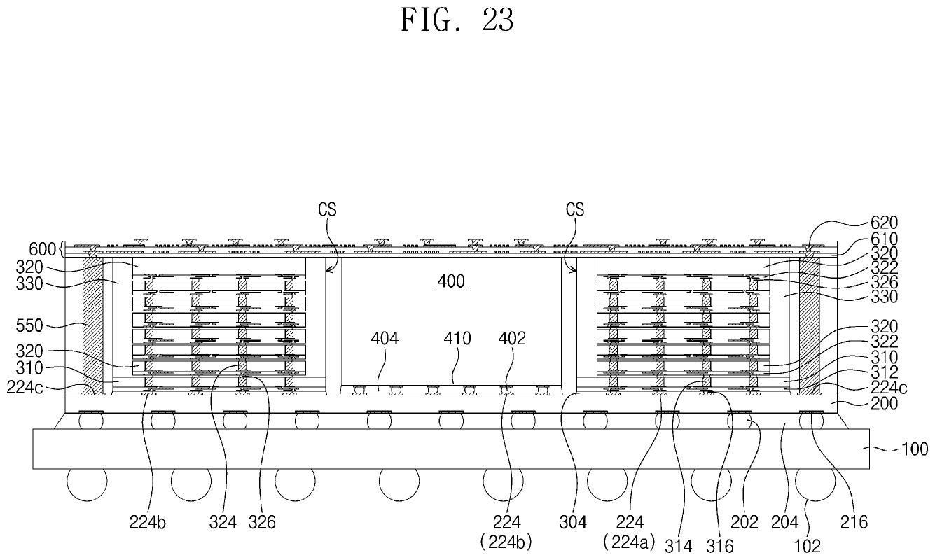

FIG. 22 illustrates a plan view showing a semiconductor package according to some embodiments of the present inventive concepts. FIG. 23 illustrates a simplified cross-sectional view showing a semiconductor package according to some embodiments of the present inventive concepts.

Referring to FIGS. 22 and 23, the chip stack CS may be provided in plural. The second semiconductor chip 400 may be disposed between the chip stacks CS. The chip stacks CS may be electrically connected through the interposer substrate 200 to the second semiconductor chip 400. The chip stacks CS may have their top surfaces coplanar with that of the second molding layer 500 and that of the second semiconductor chip 400.

The vertical connection terminals 550 may be disposed on an outer section of the interposer substrate 200. The chip stacks CS and the second semiconductor chip 400 may be positioned between the vertical connection terminals 550.

The redistribution layer 600 may be disposed on the chip stacks CS and the second semiconductor chip 400. The redistribution layer 600 may be electrically connected through the vertical connection terminals 550 to the second semiconductor chip 400 and the chip stacks CS.

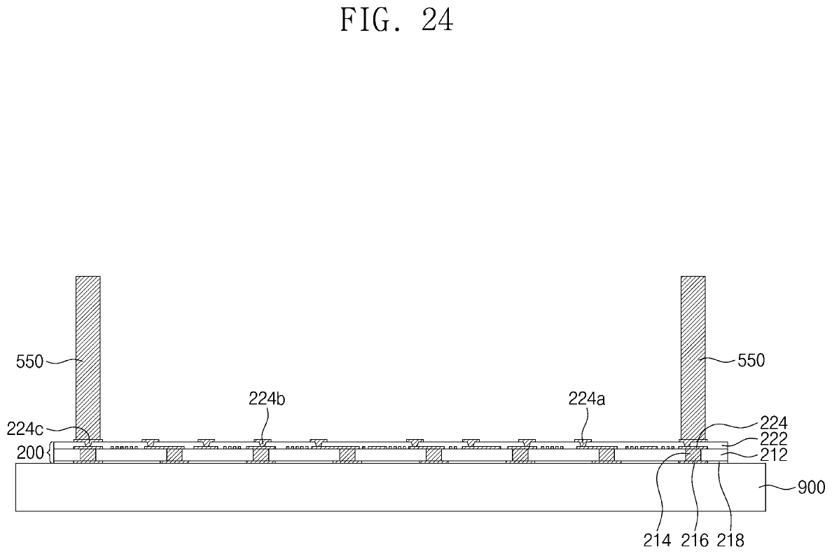

FIGS. 24 to 28 illustrate cross-sectional views showing a method of fabricating a semiconductor package according to some embodiments of the present inventive concepts.

Referring to FIG. 24, a carrier substrate 900 may be provided. The carrier substrate 900 may be a dielectric substrate including glass or polymer, or may be a conductive substrate including metal.

Although not shown, an adhesive member may be provided on a top surface of the carrier substrate 900. For example, the adhesive member may include or may be a glue tape.

To form an interposer substrate 200, interposer vias 214 may be formed to penetrate a silicon layer 212, an interposer protection layer 218 may be formed to cover a bottom surface of the silicon layer 212, interposer lower pads 216 may be formed in opening formed in the interposer protection layer 218, and a wiring member 220 may be formed to have a first substrate dielectric pattern 222 and a first substrate wiring pattern 224 on a top surface of the silicon layer 212. The interposer substrate 200 may be attached to the carrier substrate 900.

Vertical connection terminals 550 may be formed on the interposer substrate 200. For example, a sacrificial layer may be formed on the interposer substrate 200, through holes may be formed to vertically penetrate the sacrificial layer and to expose third substrate pads 224c of the interposer substrate 200, and the through holes may be filled with a conductive material to form the vertical connection terminals 550. Afterwards, the sacrificial layer may be removed.

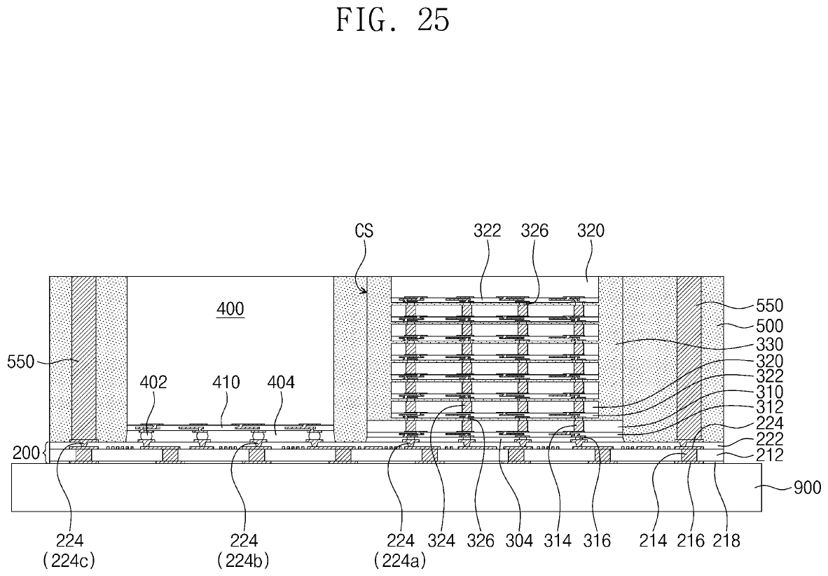

Referring to FIG. 25, a chip stack CS and a second semiconductor chip 400 may be provided on the interposer substrate 200. The chip stack CS may be the same as or similar to that discussed with reference to FIG. 1. For example, the chip stack CS may include a base semiconductor chip 310, first semiconductor chips 320 stacked on the base semiconductor chip 310, and a first molding layer 330 that surrounds the first semiconductor chips 320. The second semiconductor chip 400 may be the same as or similar to that discussed with reference to FIG. 1.

The chip stack CS may be mounted on the interposer substrate 200. The chip stack CS may be flip-chip mounted on the interposer substrate 200. The chip stack CS may be provided with base connection terminals 316 on a bottom surface thereof. The base connection terminals 316 may include or may be solder balls or solder bumps. The chip stack CS may be provided on a bottom surface with a second underfill layer 304 that surrounds the base connection terminals 316. For example, the second underfill layer 304 may be a non-conductive adhesive or a non-conductive film. When the second underfill layer 304 is a non-conductive adhesive, the second underfill layer 304 may be formed by dispensing a liquid non-conductive adhesive to coat the chip stack CS. When the second underfill layer 304 is a non-conductive film, the second underfill layer 304 may be formed by attaching a non-conductive film to the chip stack CS. After that, the chip stack CS may be aligned to allow the base connection terminals 316 to rest on first substrate pads 224a of the interposer substrate 200, and then a reflow process may be performed on the chip stack CS.

The second semiconductor chip 400 may be mounted on the interposer substrate 200. The second semiconductor chip 400 may be flip-chip mounted on the interposer substrate 200. The second semiconductor chip 400 may be provided with second connection terminals 402 on a bottom surface thereof. The second connection terminals 402 may include or may be solder balls or solder bumps. The second semiconductor chip 400 may be provided on a bottom surface with a third underfill layer 404 that surrounds the second connection terminals 402. For example, the third underfill layer 404 may be a non-conductive adhesive or a non-conductive film. When the third underfill layer 404 is a non-conductive adhesive, the third underfill layer 404 may be formed by dispensing a liquid non-conductive adhesive to coat the second semiconductor chip 400. When the third underfill layer 404 is a non-conductive film, the third underfill layer 404 may be formed by attaching a non-conductive film to the second semiconductor chip 400. Thereafter, the second semiconductor chip 400 may be aligned such that the second connection terminals 402 are rested on second substrate pads 224b of the interposer substrate 200, and then a reflow process may be performed on the second semiconductor chip 400.

A second molding layer 500 may be formed. For example, the second molding layer 500 may be formed by coating a dielectric material on the interposer substrate 200. The second molding layer 500 may cover the chip stack CS and the second semiconductor chip 400. Afterwards, a grinding process may be performed on the second molding layer 500. An upper portion of the second molding layer 500 may be partially removed. A top surface of the second molding layers 500 may be coplanar with that of the chip stack CS and that of the second semiconductor chip 400.

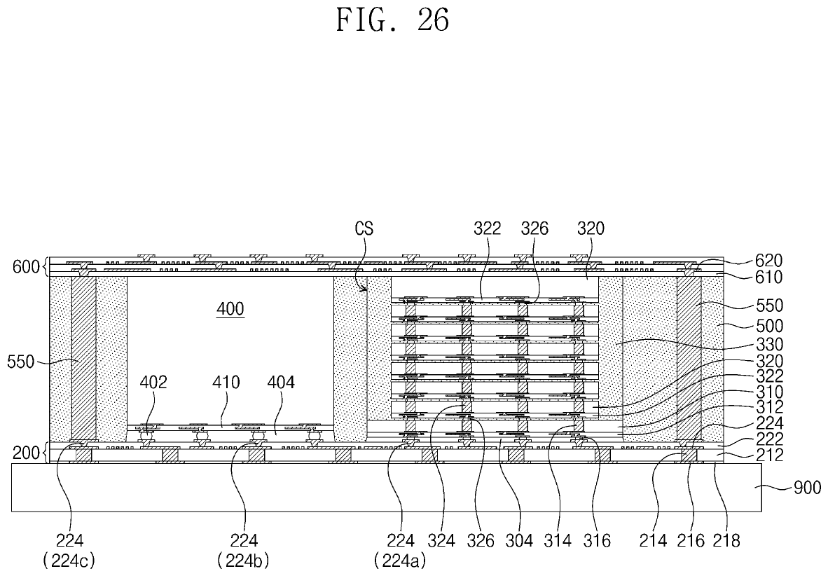

Referring to FIG. 26, a redistribution layer 600 may be formed on the second molding layer 500. For example, a second substrate dielectric pattern 610 may be formed on the second molding layer 500, and openings may be formed to penetrate the second substrate dielectric pattern 610 to expose the vertical connection terminals 550, and a second substrate wiring pattern 620 may be formed in the openings. Therefore, one wiring layer may be formed, and the processes mentioned above may be repeated to form the redistribution layer 600 having a plurality of stacked wiring lines.

Referring to FIG. 2, the carrier substrate 900 may be removed. After that, substrate terminals 202 may be formed on the interposer lower pads 216 of the interposer substrate 200, and the interposer substrate 200 may be provided on a bottom surface with a first underfill layer 204 that surrounds the substrate terminals 202, and the interposer substrate 200 may be mounted on the package substrate 100. External terminals 102 may be provided below the package substrate 100.

A semiconductor package of FIG. 2 may be fabricated through the process mentioned above.

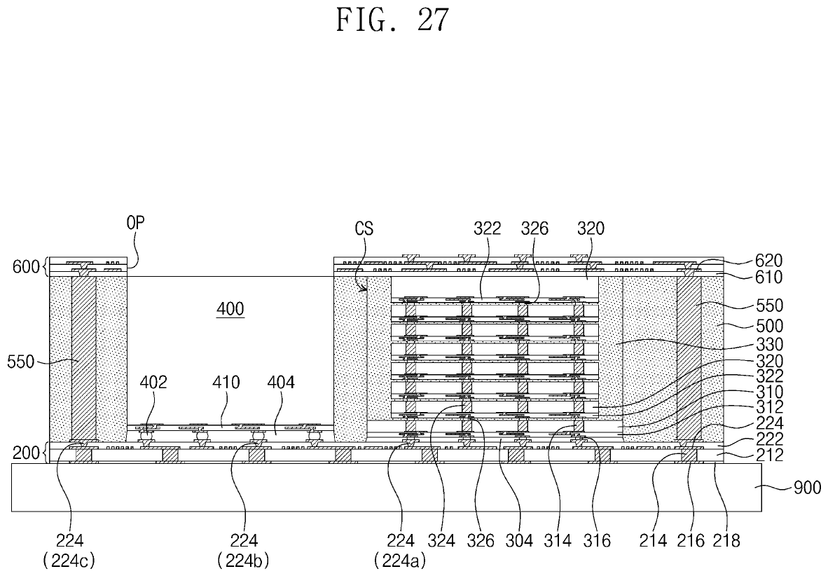

Referring to FIG. 27, on a resultant structure of FIG. 26, the redistribution layer 600 may be patterned to form an opening OP. For example, a mask pattern may be formed on the redistribution layer 600, and then the mask pattern may be used as an etching mask to perform an etching process to pattern the redistribution layer 600. The opening OP may be formed above the second semiconductor chip 400. The second substrate wiring pattern 620 of the redistribution layer 600 may not be positioned above the second semiconductor chip 400. For example, the second substrate wiring pattern 620 may not vertically overlap the second semiconductor chip 400, and the etching process may be easily performed. The opening OP may expose the top surface of the second semiconductor chip 400.

Referring to FIG. 5, the carrier substrate 900 may be removed. After that, substrate terminals 202 may be formed on the interposer lower pads 216 of the interposer substrate 200, and the interposer substrate 200 may be provided on a bottom surface with a first underfill layer 204 that surrounds the substrate terminals 202, and the interposer substrate 200 may be mounted on the package substrate 100. External terminals 102 may be provided below the package substrate 100.

A semiconductor package of FIG. 5 may be fabricated through the process mentioned above.

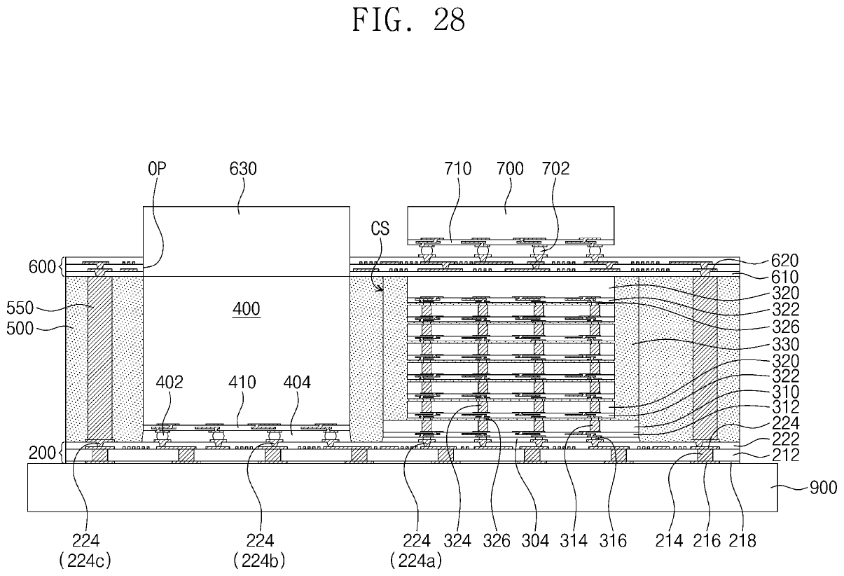

Referring to FIG. 28, on a resultant structure of FIG. 27, a third semiconductor chip 700 may be mounted on the redistribution layer 600. The third semiconductor chip 700 may be the same as or similar to that discussed with reference to FIGS. 9 to 11.

The third semiconductor chip 700 may be mounted on the redistribution layer 600. The third semiconductor chip 700 may be flip-chip mounted on the redistribution layer 600. The third semiconductor chip 700 may be provided with third connection terminals 702 on a bottom surface thereof. The third connection terminals 702 may include or may be solder balls or solder bumps. Thereafter, the third semiconductor chip 700 may be aligned such that the third connection terminals 702 are rested on the second substrate wiring pattern 620 of the redistribution layer 600, and then a reflow process may be performed on the third semiconductor chip 700.

A first dummy chip 630 may be disposed on the second semiconductor chip 400. The first dummy chip 630 may be the same as or similar to that discussed with reference to FIG. 11. The first dummy chip 630 may be inserted into the opening OP of the redistribution layer 600. A thermal interface material (TIM) may attach the first dummy chip 630 to the top surface of the second semiconductor chip 400.

Referring to FIG. 11, the carrier substrate 900 may be removed. After that, substrate terminals 202 may be formed on the interposer lower pads 216 of the interposer substrate 200, and the interposer substrate 200 may be provided on a bottom surface with a first underfill layer 204 that surrounds the substrate terminals 202, and the interposer substrate 200 may be mounted on the package substrate 100. External terminals 102 may be provided below the package substrate 100.

A semiconductor package of FIG. 11 may be fabricated through the processes mentioned above.

In a semiconductor package according to some embodiments of the present inventive concepts, a redistribution layer may be provided on a chip stack and a semiconductor chip, and vertical connection terminals may connect the redistribution layer to an interposer substrate. Therefore, a semiconductor chip, an electronic device, or an external apparatus may be separately mounted on the redistribution layer, and the semiconductor package may increase in a degree of integration. In addition, a circuit wiring line connected to the chip stack and the semiconductor chip may be provided not only on the interposer substrate, but above the chip stack and the semiconductor chip. In this configuration, the semiconductor chip, the electronic device, or the external apparatus connected to the chip stack and the second semiconductor chip may be vertically stacked on the chip stack and the second semiconductor chip. Accordingly, it may be possible to provide a compact-sized semiconductor package that occupies a small planar area.

Moreover, the redistribution layer may provide electrical wiring lines on the semiconductor chip and the chip stack and may have an opening to expose a top surface of the semiconductor chip. Therefore, heat generated from the semiconductor chip may be easily discharged through the top surface of the semiconductor chip. When the semiconductor chip includes a logic circuit, a large amount of heat may be generated from the semiconductor chip during operation thereof, and because the redistribution layer does not cover the semiconductor chip, the heat may be effectively discharged. Further, as a dummy chip is provided on the semiconductor chip, heat generated from the semiconductor chip may be effectively discharged through the dummy chip. Accordingly, it may be possible to provide a semiconductor package with improved thermal radiation properties.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

1. A semiconductor package, comprising:
an interposer substrate;
a chip stack on the interposer substrate and including a plurality of first semiconductor chips that are vertically stacked;
a second semiconductor chip on the interposer substrate and horizontally spaced apart from the chip stack;
a molding layer disposed on the interposer substrate and surrounding a side surface of each of the chip stack and the second semiconductor chip;
a redistribution layer on the molding layer; and
a plurality of conductive posts that vertically penetrate the molding layer and connect the interposer substrate to the redistribution layer.

2. The semiconductor package of claim 1, wherein:
the redistribution layer has a through hole that vertically penetrates the redistribution layer, and
the through hole is above the second semiconductor chip.

3. The semiconductor package of claim 2, further comprising a first dummy chip in the through hole.

4. The semiconductor package of claim 3,
wherein the first dummy chip contacts a top surface of the second semiconductor chip.

5. The semiconductor package of claim 2, wherein:
a top surface of the second semiconductor chip is coplanar with a top surface of the molding layer, and
the through hole exposes the top surface of the second semiconductor chip.

6. The semiconductor package of claim 2, wherein:
a top surface of the second semiconductor chip is at a level lower than a level of a top surface of the molding layer, and
the through hole penetrates the redistribution layer and an upper portion of the molding layer and exposes the top surface of the second semiconductor chip.

7. The semiconductor package of claim 2, further comprising:
a thermal radiation member on a top surface of the second semiconductor chip,
wherein the top surface of the second semiconductor chip is at a level lower than a level of a top surface of the molding layer, and
wherein the through hole exposes a top surface of the thermal radiation member.

8. The semiconductor package of claim 1,
wherein each of the plurality of conductive posts includes:
a lower post connected to the interposer substrate; and
an upper post on the lower post and connected to the redistribution layer, and
wherein a width of the lower post is greater than a width of the upper post.

9. (canceled)

10. The semiconductor package of claim 1, further comprising at least one third semiconductor chip mounted on the redistribution layer.

11. The semiconductor package of claim 1, further comprising a second dummy chip on the redistribution layer.

12. (canceled)

13. The semiconductor package of claim 1,
wherein, when viewed in a plan view, the plurality of conductive posts include a first column of conductive posts and a second column of conductive posts, and the chip stack and the second semiconductor chip are disposed in a space between the first column of conductive posts and the second column of conductive posts.

14. The semiconductor package of claim 1,
wherein each of the plurality of conductive posts has a pillar shape that extends in a direction perpendicular to a top surface of the interposer substrate.

15. The semiconductor package of claim 1,
wherein the plurality of conductive posts are disposed in a space between the chip stack and the second semiconductor chip.

16-18. (canceled)

19. A semiconductor package, comprising:
a substrate;
a chip stack on the substrate and including a plurality of memory chips that are vertically stacked;
a logic chip on the substrate and horizontally spaced apart from the chip stack;
a molding layer that surrounds a side surface off each of the chip stack and the logic chip;
a redistribution layer on the molding layer and having a through hole above the logic chip, the through hole vertically penetrating the redistribution layer; and
a dummy chip in the through hole and contacting a top surface of the logic chip.

20. The semiconductor package of claim 19, further comprising a vertical connection terminal that vertically penetrates the molding layer and connects the substrate to the redistribution layer.

21. The semiconductor package of claim 20,
wherein the vertical connection terminal includes a conductive post that extends in a direction perpendicular to a top surface of the substrate.

22-24. (canceled)

25. The semiconductor package of claim 19, wherein:
the top surface of the logic chip is coplanar with a top surface of the molding layer, and
the through hole exposes the top surface of the logic chip.

26. The semiconductor package of claim 19, wherein:
the top surface of the logic chip is at a level lower than a level of a top surface of the molding layer, and
the through hole penetrates the redistribution layer and an upper portion of the molding layer and exposes the top surface of the logic chip.

27. (canceled)

28. The semiconductor package of claim 19, further comprising at least one additional semiconductor chip mounted on the redistribution layer.

29. (canceled)

30. A semiconductor package, comprising:
a package substrate;
an interposer substrate on the package substrate;
a chip stack on the interposer substrate, the chip stack including a plurality of first semiconductor chips that are vertically stacked;
a second semiconductor chip on the interposer substrate and horizontally spaced apart from the chip stack;
a molding layer disposed on the interposer substrate and surrounding a side surface of each of the chip stack and the second semiconductor chip;
a redistribution layer on the molding layer; and
a vertical connection terminal that vertically penetrates the molding layer and connects the interposer substrate to the redistribution layer.

31-43. (canceled)
